(19) United States
(12) Patent Application Publication
(10) Pub. No.: US 2024/0162136 A1
(43) Pub. Date: May 16, 2024

(54) PACKAGE FOR A LATERAL POWER TRANSISTOR

(71) Applicant: Infineon Technologies Austria AG, Villach (AT)

(72) Inventors: Kok Yau Chua, Melaka (MY); Edward Andrew Jones, Villach (AT); Milad Mostofizadeh, München (DE); Chee Yang Ng, Muar (MY); Klaus Schiess, Allensbach (DE); Guan Choon Matthew Nelson Tee, Batu Berendam (MY)

(21) Appl. No.: 18/488,084

(22) Filed: Oct. 17, 2023

(30) Foreign Application Priority Data
Nov. 10, 2022 (EP) 22206772.0

(51) Int. Cl. H01L 23/498

(52) U.S. Cl. CPC H01L 23/49844; H01L 23/49827

(57) ABSTRACT

A transistor package includes a power transistor chip having first and second opposite sides. The first side has source, drain, and gate electrode metallizations. A multi-layer laminate substrate includes: a first structured metal layer facing the first side of the chip and electrically connected to the source electrode metallization, the drain electrode metallization, and the gate electrode metallization; a second structured metal layer having a source package terminal pad, a source sense package terminal pad, a drain package terminal pad, and a gate package terminal pad; at least one insulating layer between the structured metal layers; and vias running through the insulating layer and connecting segments of the first structured metal layer to the terminal pads of the second structured metal layer.

### TECHNICAL FIELD

This disclosure relates generally to the technique of semiconductor packaging, and in particular to a transistor package for a lateral transistor device.

### BACKGROUND

Transistor packages are widely used as electronic switches in a variety of electronic circuits. Higher efficiency, increased power density, lower switching losses, faster switching times, lower device parasitics and lower cost are among the key goals for next generation transistor package design.

The transistor switching performance is limited by parasitic elements from the transistor package and the board. In particular, the parasitic common source inductance causes switching losses.

Conventional approaches to reduce device parasitics for fast switching and to improve thermal behavior are to use leadless packages and/or to use clips for connecting the load electrodes of a semiconductor transistor chip to the respective terminals of the transistor package.

Existing package solutions use an additional pin for a source Kelvin connection as a reference potential for the gate driving voltage. However, the presence of a source Kelvin pin and source Kelvin connection degrades the package inductance and package resistance.

### SUMMARY

According to an aspect of the disclosure, a transistor package for a power transistor chip includes the power transistor chip having a first side and a second side opposite the first side. The first side comprises a source electrode metallization, a drain electrode metallization, and a gate electrode metallization. The package further includes a multi-layer laminate substrate to which the power transistor chip is connected. The multi-layer laminate substrate comprises a first structured metal layer facing the first side of the power transistor chip and being electrically connected to the source electrode metallization, the drain electrode metallization and the gate electrode metallization, a second structured metal layer comprising a source package terminal pad, a source sense package terminal pad, a drain package terminal pad and a gate package terminal pad, at least one insulating layer disposed between the first structured metal layer and the second structured metal layer, and a plurality of vias running through the insulating layer and connecting segments of the first structured metal layer to the terminal pads of the second structured metal layer. The first structured metal layer, the second structured metal layer and the plurality of vias are designed such that a gate-source current path between the power transistor chip and the source sense package terminal pad is provided only on one of the first and second structured metal layers while a drain-source current path between the source electrode metallization of the power transistor chip and the source package terminal pad is at least on the other structured metal layer of the multi-layer laminate substrate.

### BRIEF DESCRIPTION OF THE DRAWINGS

In the drawings, like reference numerals designate corresponding similar parts. The features of the various illustrated embodiments can be combined unless they exclude each other and/or can be selectively omitted if not described to be necessarily required. Embodiments are depicted in the drawings and are exemplarily detailed in the description which follows.

FIG. 1 is a perspective top view of an example of a transistor package illustrated in a semi-transparent representation.

FIG. 2A is a bottom view of a transistor package in accordance with a first variant.

FIG. 2B is a bottom view of a transistor package in accordance with a second variant.

FIG. 3 is a plan view of a portion of an exemplary electrode metallization layout of a power transistor chip.

FIG. 4A is a plan view of a first structured metal layer facing the power transistor chip according to a first example of a transistor package.

FIG. 4B is a plan view of a second structured metal layer the transistor package of FIG. 4A.

FIG. 5A is a schematic cross-sectional view of the transistor package of FIGS. 4A, 4B along line A-A′ of FIGS. 4A and 4B.

FIG. 5B is a schematic cross-sectional view of the transistor package of FIGS. 4A, 4B along line B-B′ of FIGS. 4A and 4B.

FIG. 6A is a plan view of a first structured metal layer facing the power transistor chip according to a second example of a transistor package.

FIG. 6B is a plan view of a second structured metal layer the transistor package of FIG. 6A.

FIG. 7A is a schematic cross-sectional view of the transistor package of FIGS. 6A, 6B along line A-A′ of FIGS. 6A and 6B.

FIG. 7B is a schematic cross-sectional view of the transistor package of FIGS. 6A, 6B along line B-B′ of FIGS. 6A and 6B.

FIG. 8A is a plan view of a first structured metal layer facing the power transistor chip according to a third example of a transistor package.

FIG. 8B is a plan view of a second structured metal layer the transistor package of FIG. 8A.

FIG. 9A is a schematic cross-sectional view of the transistor package of FIGS. 8A, 8B along line A-A′ of FIGS. 8A and 8B.

FIG. 9B is a schematic cross-sectional view of the transistor package of FIGS. 8A, 8B along line B-B′ of FIGS. 8A and 8B.

FIG. 10 is a perspective top view of a detail of FIG. 1.

### DETAILED DESCRIPTION

As used in this specification, the terms “electrically connected” or “electrically coupled” or similar terms are not meant to mean that the elements are directly contacted together; intervening elements may be provided between the “electrically connected” or “electrically coupled” elements, respectively. However, in accordance with the disclosure, the above-mentioned and similar terms may, optionally, also have the specific meaning that the elements are directly contacted together, i.e. that no intervening elements are provided between the “electrically connected” or “electrically coupled” elements, respectively.

Further, the words “over” or “beneath” with regard to a part, element or material layer formed or located or arranged “over” or “beneath” a surface may be used herein to mean that the part, element or material layer be located (e.g. placed, formed, arranged, deposited, etc.) “directly on” or “directly under”, e.g. in direct contact with, the implied surface. The word “over” or “beneath” used with regard to a part, element or material layer formed or located or arranged “over” or “beneath” a surface may, however, either be used herein to mean that the part, element or material layer be located (e.g. placed, formed, arranged, deposited, etc.) “indirectly on” or “indirectly under” the implied surface, with one or more additional parts, elements or layers being arranged between the implied surface and the part, element or material layer.

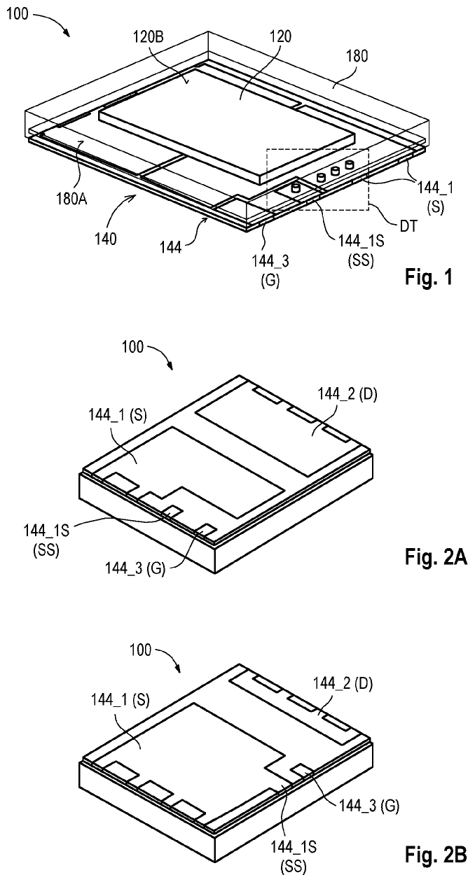

Referring to FIG. 1, a transistor package 100 includes a power transistor chip 120. The power transistor chip 120 has a first side (not visible in FIG. 1) and a second side 120B opposite the first side.

The semiconductor transistor chip 120 is a lateral device, i.e. the first side comprises a source electrode metallization, a drain electrode metallization, and a gate electrode metallization. The metallizations are all disposed on the same (first) side of the semiconductor transistor chip 120. In other words, the lateral semiconductor transistor chip 120 is implemented in the transistor package 100 in a flip-chip orientation.

The power transistor chip 120 may be, e.g., capable of switching high currents and/or medium or high voltages (e.g. more than 50 V or 100 V or 200 V or 300 V blocking voltage). In particular, exemplary transistor packages as disclosed herein may operate in the medium voltage (MV) range, in which the blocking voltage is equal to or greater than or less than 200 V or 150 V or 100 V or 50 V.

The power transistor chip 120 may be of different types. Examples described herein are, in particular, directed, e.g., to HEMT (high electron mobility transistor) devices. More specifically, the semiconductor transistor chip 120 referred to herein may, e.g., be a III-V compound semiconductor chip having, e.g., a high band gap. The power transistor chip 120 may, e.g., be a GaN chip. In this case, the GaN chip 120 may be a lateral GaN-on-substrate device such as a GaN-on-Si device or a GaN-on-SiC device or a GaN-on-sapphire device, for example.

The transistor package 100 may include a multi-layer laminate substrate (will be described further below) to which the power transistor chip 120 is connected (e.g. mounted).

The source, drain and gate electrode metallizations of the power transistor chip 120 are connected via a first structured metal layer (will be described further below) of the multi-layer laminate substrate to a second structured metal layer 144 of multi-layer laminate substrate. The second structured metal layer 144 may be exposed at the bottom of the transistor package 100 and includes a source package terminal pad 144_1 also denoted by S, a drain package terminal pad 144_2 also denoted by D, and a gate package terminal pad 144_3 also denoted by G, see, e.g., the exemplary footprints of transistor packages 100 shown in FIGS. 2A and 2B.

As illustrated in the semi-transparent representation of FIG. 1, the power transistor chip 120 may be embedded in a mold compound 180. The mold compound 180 may cover the multi-layer laminate substrate to which the power transistor chip 120 is connected. A periphery of the mold compound 180 is denoted by reference sign 180A.

The second structured metal layer 144, providing for the package terminals, further includes a source sense package terminal pad 144_1S also denoted by SS. The source sense package terminal pad 144_1S, which is also referred to as Kelvin sense terminal pad in the art, may, e.g., be implemented either as an separate (insular) package terminal pad (FIG. 2A) or as a terminal pad which is continuous with the source package terminal 144_1 (FIG. 2B). As will be described in the following, both variants (FIG. 2A: separate source sense package terminal pad 144_1S; or FIG. 2B: integral source sense package terminal pad 144_1S) can be designed to provide low device parasitics and therefore fast switching of transistor packages 100 described herein.

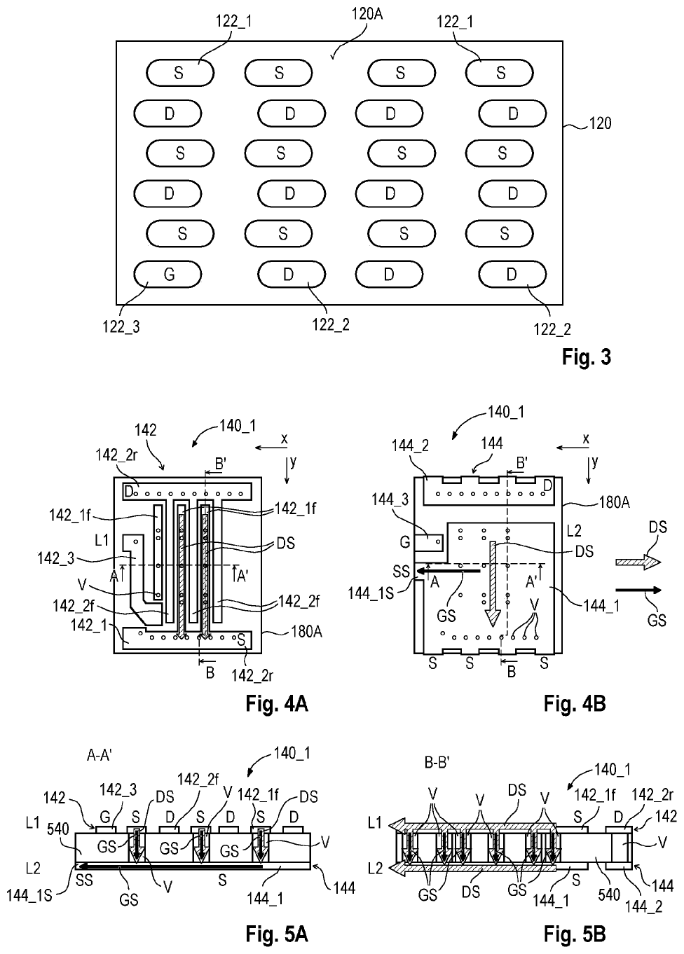

FIG. 3 is a partial plan view illustration a portion of an exemplary layout of source, drain and gate electrode metallizations at the first side 120A of the power transistor 120. The layout is shown from top, i.e. as it would be seen through the power transistor chip 120.

A source electrode metallization 122_1 may include a plurality of source contact pads (S), and a drain electrode metallization 122_2 may include a plurality of drain contact pads (D). Further, a gate electrode metallization 122_3 is provided.

The plurality of source contact pads (S) may, e.g., be arranged in a number of (horizontal) rows parallel to the longitudinal side of the power transistor chip 120. Likewise, the plurality of drain contact pads (D) may be arranged in a number of (horizontal) rows parallel with the rows of the source contact pads (S). In the example shown in FIG. 3, the rows of source contact pads (S) and the rows of drain contact pads (D) are interleaved (or alternating). Further, the source contact pads (S) and the drain contact pads D) are offset from each other in the longitudinal (horizontal) direction. The gate electrode metallization 122_3 may be arranged at a corner of the power transistor chip 120 and may, e.g., be formed by as single gate contact pad (G).

The contact pad layout at the first side 120A of the power transistor chip 120 may, e.g., not include a source sense pad. That is, the multi-layer laminate substrate 140 (but, e.g., not an integrated circuitry of the power transistor chip 120) may provide the internal package interconnects between the source contact pads (S) of the power transistor chip 120 and the source package terminal pad 144_1 and the source sense package terminal pad 144_1S, respectively, of the transistor package 100.

The (exemplary) layout of the source, drain and gate metallization 122_1, 122_2, 122_3 of the power transistor chip 120 apparently needs to be re-routed by a package-internal interconnect in order to provide for a layout of package terminal pads 144_1, 144_2, 144_3 and 144_1S as, e.g., shown in FIGS. 1A or 2A. Re-routing is carried out by the multi-layer laminate substrate 140.

FIGS. 4A-4B and 5A-5B illustrate a first example of a multi-layer laminate substrate 140, referred to as multi-layer laminate substrate 140_1 in the following. The multi-layer laminate substrate 140_1 includes a first structured metal layer 142, also referred to as L1 metal, and the second structured metal layer 144, also referred to as L2 metal.

The first structured metal layer 142 faces the first side 120A of the power transistor chip 120. The first structured metal layer 142 may, e.g., include a multi-finger source segment 142_1, wherein fingers 142_1f of the multi-finger source segment 142_1 are connected to the source contact pads (S) of the source electrode metallization 122_1 of the power transistor chip 120. Further, the first structured metal layer 142 may, e.g., include a multi-finger drain segment 142_2 having fingers 142_2f connected to the drain contact pads (D) of the drain electrode metallization 122_2 of the power transistor chip 120. The fingers 142_1f and the fingers 142_2f may, e.g., be interdigitated so as to allow to separately connect to the source contact pads (S) and the drain contact pads (S) at the first side 120A of the power transistor chip 120 (see, e.g., FIG. 3).

Further, the first structured metal layer 142 may include a gate segment 142_3 which connects to the gate contact pad 122_3 of the power transistor chip 120.

It is to be noted that a variety of different layouts of the source (S), drain (D) and gate (G) contact pads of the metallizations 122_1, 122_2, 122_3 at the first side 120A of the power transistor chip 120 is possible. Correspondingly, the layout of the first structured metal layer 142, which is adapted to the layout of the source (S), drain (D) and gate (G) contact pads of the metallizations 122_1, 122_2, 122_3 of the power transistor chip 120, may be designed in a variety of different patterns.

In many examples the layout of the first structured metal layer 142 is chosen to route the drain and source currents to different (e.g. opposite) sides of the transistor package 100. In the specific example shown in FIGS. 4A-5B, this separation of drain and source current is carried out by the fingers 142_1f, 142_2f of the multi-finger source and drain segments 142_1, 142_2, respectively. To this end, the fingers 142_1f or at least a part thereof (as in the example shown) may be connected to a rail portion 142_1r of the multi-finger source segment 142_1. Likewise, the fingers 142_2f of the multi-finger drain segment 142_2 may be connected to a rail portion 142_2r of the multi-finger drain segment 142_2, wherein the rail portions 142_1r and 142_2r may be located at opposite sides of the transistor package 100.

The rail portions 142_1r and 142r may, e.g., be parallel with each other and may, e.g., extend in X-direction. The fingers 142_1f, 142_2f may, e.g., be parallel with each other and may, e.g., extend in Y-direction, which is perpendicular to the X-direction.

FIG. 4B is a plan view of the second structured metal layer 144. The second structured metal layer 144 includes the source (S) package terminal pad 144_1, the drain (D) package terminal pad 144_2 and the gate (G) package terminal pad 144_3. Further, a source sense (SS) package terminal pad 144_1S is provided.

In a first example, the source sense (SS) package terminal pad 144_1S and the source (S) package terminal pad 144_1 are formed by a continuous metal segment of the second structured metal layer 144.

At least one insulating layer 540 is disposed between the first structured metal layer 142 (L1) and the second structured metal layer 144 (L2). A plurality of vias V is running through the insulating layer 540. The vias V connect segments of the first structured metal layer (L1) 142 to the terminal pads 144_1, 144_2, 144_3, 144_1S of the second structured metal layer 144 (L2). Vias V are indicated in FIGS. 4A-4B by circles.

In FIGS. 4A to 5B the drain-source current path DS and the gate-source current path GS are indicated by arrows. The (large) drain-source current is flowing along the drain-source current path DS, while the (small) gate-source current is flowing along the gate-source current path GS.

As apparent from FIGS. 4A to 5B, the drain-source current path DS between the source electrode metallization 122_1 of the power transistor chip 120 and the source (S) package terminal pad 144_1 flows on (at least) two structured layers of the multi-layer laminate substrate 140_1, namely on the first structured metal layer 142 (L1) and on the second structured metal layer 144 (L2). On the other hand, the gate-source current path GS between the source electrode metallization 122_1 of the power transistor chip 120 and the source sense (SS) package terminal pad 144_1S is provided only on one of the first and second structured metal layers 142 (L1), 144 (L2), namely on the second structured metal layer 144 (L2).

For example, the drain-source current path DS on the first and second structured metal layers 142, 144 is in the lateral Y-direction and the gate-source current path GS on the second structured metal layer 144 (L2) only is in the lateral X-direction, wherein the lateral Y-direction and the lateral X-direction are different from each other and, e.g., perpendicular to each other.

In other words, while the drain-source current flows on two layers L1, L2 of the transistor package 100 in the Y-direction, the gate-source current only flows on one of those two layers (here: layer L2) in the X-direction, thereby partly decoupling the two current paths DS and GS.

Further, the gate segment 142_3 which connects the gate contact metallization 122_3 of the power transistor chip 120 through vias V to the gate (G) package terminal pad 144_3 of the transistor package 100 may be designed, e.g., to allow the gate (G) package terminal pad 144_3 to be located at a side of the transistor package 100 oriented in Y direction (this is also referred to as a “center gate layout”). That is, the source package terminal pad 144_1 may be arranged along a first side of the transistor package 100, the drain package terminal pad 144_2 may be arranged along a second side opposite the first side of the transistor package 100 and the gate package terminal pad 144_3 may be arranged at a third side of the transistor package in a region spaced apart from a corner of the first or second side of the transistor package 100.

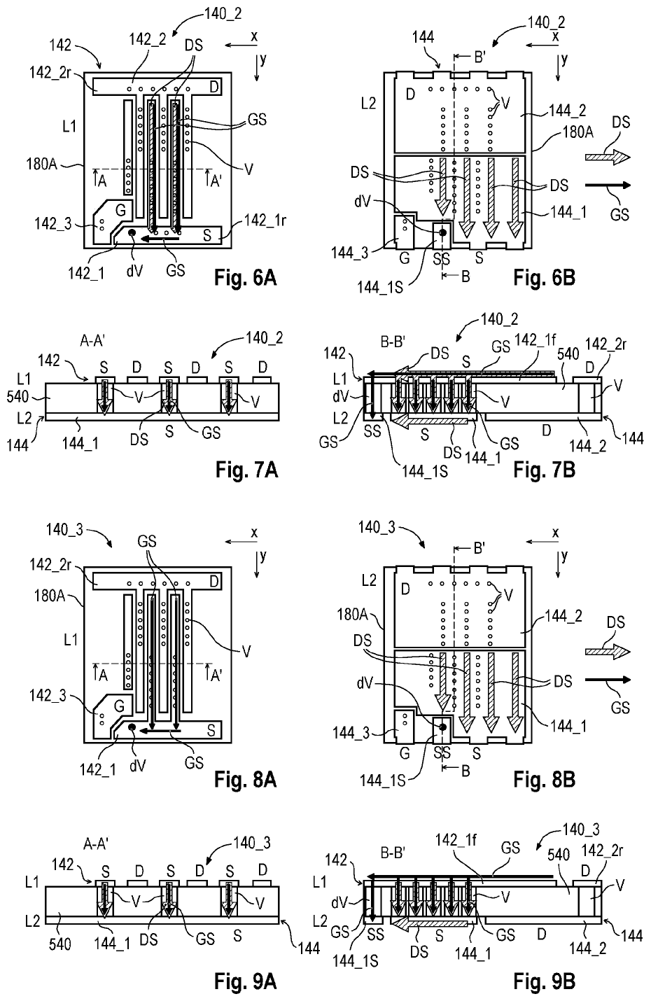

FIGS. 6A to 7B illustrate a second example of a multi-layer laminate substrate 140, referred to as multi-layer laminate substrate 140_2 in the following. The multi-layer laminate substrate 140_2 may be used in a transistor package in accordance with the first variant (see FIG. 2A). In other words, the source sense (SS) package terminal pad 144_1S and the source (S) package terminal pad 144_1 are formed by separate metal segments of the second structured metal layer 144 (L2).

As illustrated in FIGS. 6A to 7B, the drain-source current path DS is on the first and second structured metal layers 142 (L1) and 144 (L2), whereas the gate-source current path GS is only on the first structured metal layer 142 (L1). The drain-source current path DS on the first and second structured metal layers 142 (L1) and 144 (L2) is, e.g., in the lateral Y-direction. The gate-source current path GS on the first structured metal layer 142 is also, at least partially, in the Y-direction. Further, gate-source current path GS may be (partially) in the X-direction along the rail 142_1r to a dedicated via dV through which the separate source sense (SS) package terminal pad 144_1S is connected to the first metal layer 142 (L1). No drain-source current is flowing through the dedicated via dV.

In other words, in the second example of a transistor package 100 the drain-source current flows on two metal layers L1, L2 of the multi-layer laminate substrate 140 in the Y-direction, while the gate-source current only flows on one (namely L1) of those two metal layers L1, L2 in (at least partially) the Y-direction and utilizes the dedicated via dV to connect to the insular source sense (SS) package terminal pad 144_1S at the package footprint.

Further, the gate segment 142_3 which connects the gate contact metallization 122_3 of the power transistor chip 120 through vias V to the gate (G) package terminal pad 144_3 of the transistor package 100 may be, e.g., designed to allow the gate (G) package terminal pad 144_3 to be located at a corner of the transistor package 100 (this is also referred to as a “corner gate layout”). For example, the source package terminal pad 144_1 may be arranged along a first side of the transistor package 100, the drain package terminal pad 144_2 may be arranged along a second side opposite the first side of the transistor package 100 and the gate package terminal pad 144_3 may be arranged at a corner of the first side of the transistor package 100.

FIGS. 8A to 9B illustrate a third example of a transistor package 100 which includes a third example of a multi-layer laminate substrate 143, referred to as multi-layer laminate substrate 140_3 in the following. Similar to the multi-layer laminate substrate 140_2, the semiconductor package uses a dedicated via dV connecting to an insular source sense (SS) package terminal pad 144_1S. Differently stated, the source sense (SS) package terminal pad 144_1S and the source (S) package terminal pad 144_1 are formed by separate metal segments of the second structured metal layer 144. However, the third example of a transistor package (FIGS. 8A to 9B) distinguishes from the second example (FIGS. 6A to 7B) in that the drain-source current path DS is only on the second structured metal layer 144 (L2) and the gate-source current path GS is only on the first structured metal layer 142 (L1). The multi-layer laminate substrate 140_3 provides fully decoupled drain-source and gate-source current paths DS and GS.

For example, the drain-source current path DS on the second structured metal layer 144 (L2) is in the Y-direction, and the gate-source current path GS on the first structured metal layer 142 (L1) is also, at least partially, in the Y-direction.

Further, the gate segment 142_3 which connects the gate contact metallization 122_3 of the power transistor chip 120 through vias V to the gate (G) package terminal pad 144_3 of the transistor package 100 may, e.g., designed to allow the gate (G) package terminal pad 144_3 to be located at a corner of the transistor package 100 (“corner gate layout”). Reference is made to the above description of a “corner gate layout” to avoid reiteration.

The various implementations according to the first, second and third examples disclosed above are summarized in Table 1.

TABLE 1

| | ex. 1 (140_1) | ex. 2 (140_2) | ex. 3 (140_3) |
|---|---|---|---|
| DS current through | L1 + L2 | L1 + L2 | L2 |
| GS current through | L2 | L1 | L1 |
| Dedicated via dV and | No | Yes | Yes |
| insular SS pad | | | |

While examples 1 and 2 (multi-layer laminate substrates 140_1 and 140_2, respectively) provide for partial decoupling of the drain-source current and the gate-source current, the example 3 fully decouples the drain-source current path DS and the gate-source current pat GS. In all examples 1 to 3 the source sense (SS) terminal pad 144_1S (“Kelvin source pad”) for the gate-source current is connected to the power transistor chip 120 on only one of the metal layers L1, L2, and the at least one other metal layer L2 or L1, respectively, is used to provide an alternate path for the drain-source current between the source electrode metallization 122_1 of the power transistor chip 120 and the (power) source package terminal pad 144_1 of the transistor package 100. Further, it is to be noted that a dedicated via dV can be used either in a partially decoupled implementation (e.g. ex. 2, 140_2) or a fully decoupled implementation (e.g. ex. 3, 140_3). Moreover, center gate or corner gate layouts may be used in any of the implementations as disclosed.

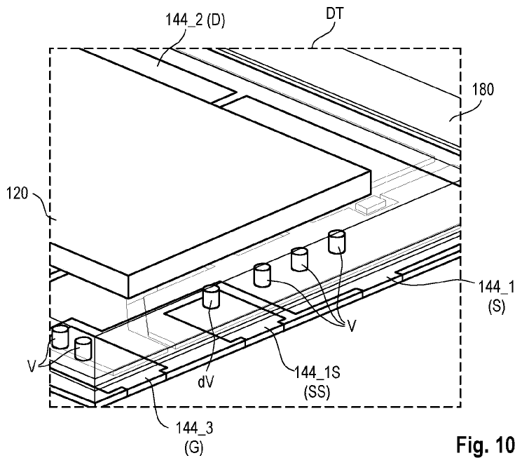

FIG. 10 is a perspective top view of detail DT of FIG. 1. The semi-transparent representation shows the dedicated via dV connecting to the insular source sense (SS) package terminal pad 144_1S (SS). Reference is made to FIGS. 2A and FIGS. 6A to 9B in which implementations in line with such footprint layout are presented, for example.

Due to the face-down orientation of the semiconductor transistor chip 120, the transistor packages 100 disclosed herein allow to achieve low parasitics for fast switching and high thermal connectivity. In all examples, the array of vias V provides a vertical connection structure of low parasitic inductance in the multi-layer laminate structure 140 to connect the source electrode metallization 122_1 of the power transistor chip 120 to the source package terminal pad 144_1 of the transistor package 100. In addition, the partially or fully decoupling of the (large) load DS and the (small) source sense GS currents allows to offer a source Kelvin IO pin (i.e. the source sense package terminal pad 144_1S) with minimum parasitic inductance. In particular, a dedicated via dV connecting the source electrode metallization 122_1 of the power transistor chip 120 to the source sense (SS) package terminal pad 144_1S of the transistor package 100 may improve the switching frequency.

Further, for example given a GaN semiconductor transistor chip 120 is used, the face-down orientation of the GaN transistor chip 120 in combination with the multi-layer laminate substrate 140, which can be used as a routable base of the transistor package 100, allows to align the transistor package footprint with the footprints of common MOSFET (Metal Oxide Semiconductor Field Effect Transistor) packages which, however, cannot fulfill the fast switching requirements of the transistor package 100 described herein.

The multi-layer laminate substrate 140 may be represented by a variety of different structures and formed by a variety of different methods of manufacturing. For example, the multi-layer laminate substrate 140 may comprise or be a separate PCB (Printed Circuit Board) on which the power transistor chip 120 chip is mounted. In other examples, the multi-layer laminate substrate may be generated at wafer level by, e.g., embedded wafer level packaging techniques, also known as eWLP in the art. In eWLP, the transistor packages 100 are separated from an “artificial wafer” in which an array of power transistor chips 120 is embedded in a continuous mold compound wafer structure.

The following examples pertain to further aspects of the disclosure:

Example 1 is a transistor package for a power transistor chip. The transistor package includes the power transistor chip having a first side and a second side opposite the first side. The first side comprises a source electrode metallization, a drain electrode metallization, and a gate electrode metallization. The package further includes a multi-layer laminate substrate to which the power transistor chip is connected. The multi-layer laminate substrate comprises a first structured metal layer facing the first side of the power transistor chip and being electrically connected to the source electrode metallization, the drain electrode metallization and the gate electrode metallization, a second structured metal layer comprising a source package terminal pad, a source sense package terminal pad, a drain package terminal pad and a gate package terminal pad, at least one insulating layer disposed between the first structured metal layer and the second structured metal layer, and a plurality of vias running through the insulating layer and connecting segments of the first structured metal layer to the terminal pads of the second structured metal layer. The first structured metal layer, the second structured metal layer and the plurality of vias are designed such that a gate-source current path between the power transistor chip and the source sense package terminal pad is provided only on one of the first and second structured metal layers while a drain-source current path between the source electrode metallization of the power transistor chip and the source package terminal pad is at least on the other structured metal layer of the multi-layer laminate substrate.

In Example 2, the subject matter of Example 1 can optionally include wherein the source sense package terminal pad and the source package terminal pad are formed by a continuous metal segment of the second structured metal layer.

In Example 3, the subject matter of Example 1 or 2 can optionally include wherein the drain-source current path is on the first and second structured metal layers, and the gate-source current path is only on the second structured metal layer.

In Example 4, the subject matter of Example 3 can optionally include wherein the drain-source current path on the first and second structured metal layers is in a lateral direction Y and the gate-source current path on the second structured metal layer is in a lateral direction X, wherein the lateral direction Y and the lateral direction X are different from each other.

In Example 5, the subject matter of Example 1 can optionally include wherein the source sense package terminal pad and the source package terminal pad are formed by separate metal segments of the second structured metal layer.

In Example 6, the subject matter of Example 5 can optionally include wherein the drain-source current path is on the first and second structured metal layers, and the gate-source current path is only on the first structured metal layer.

In Example 7, the subject matter of Example 6 can optionally include wherein the drain-source current path on the first and second structured metal layers is in a lateral direction Y and the gate-source current path on the first structured metal layer is also at least partially in the lateral direction Y.

In Example 8, the subject matter of Example 5 can optionally include wherein the drain-source current path is only on the second structured metal layer, and the gate-source current path is only on the first structured metal layer.

In Example 9, the subject matter of Example 8 can optionally include wherein the drain-source current path on the second structured metal layer is in a lateral direction Y and the gate-source current path on the first structured metal layer is also at least partially in the lateral direction Y.

In Example 10, the subject matter of any of Examples 5 to 9 can optionally include wherein the separate source sense package terminal pad is connected to the first metal layer by a dedicated via through which no drain-source current is flowing.

In Example 11, the subject matter of any of the preceding Examples can optionally include wherein the first structured metal layer comprises a multi-finger drain segment connected to the drain electrode metallization and a multi-finger source segment connected to the source electrode metallization, wherein the multi-finger drain segment and the multi-finger source segment are interdigitated.

In Example 12, the subject matter of any of the preceding Examples can optionally include wherein the source package terminal pad is arranged along a first side of the transistor package, the drain package terminal pad is arranged along a second side opposite the first side of the transistor package and the gate package terminal pad is arranged at a corner of the first side of the transistor package.

In Example 13, the subject matter of any of the Examples 1 to 11 can optionally include wherein the source package terminal pad is arranged along a first side of the transistor package, the drain package terminal pad is arranged along a second side opposite the first side of the transistor package and the gate package terminal pad is arranged at a third side of the transistor package in a region spaced apart from a corner of the first or second side of the transistor package.

In Example 14, the subject matter of any of the preceding Examples can optionally further include a mold compound embedding the power transistor chip and covering the multi-layer laminate substrate outside the area where the power transistor chip is placed.

In Example 15, the subject matter of any of the preceding Examples can optionally include wherein the power transistor chip is a HEMT transistor chip and/or a GaN transistor chip.

In Example 16, the subject matter of any of the preceding Examples can optionally include wherein the power transistor chip is configured to switch drain-source voltages equal to or greater than 50 V or 100 V or 150 V or 200 V.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

What is claimed is:

1. A transistor package, comprising:
a power transistor chip having a first side and a second side opposite the first side, the first side comprising a source electrode metallization, a drain electrode metallization, and a gate electrode metallization; and
a multi-layer laminate substrate to which the power transistor chip is connected, the multi-layer laminate substrate comprising:
a first structured metal layer facing the first side of the power transistor chip and being electrically connected to the source electrode metallization, the drain electrode metallization, and the gate electrode metallization;
a second structured metal layer comprising a source package terminal pad, a source sense package terminal pad, a drain package terminal pad, and a gate package terminal pad;
at least one insulating layer disposed between the first structured metal layer and the second structured metal layer; and
a plurality of vias running through the insulating layer and connecting segments of the first structured metal layer to the terminal pads of the second structured metal layer,
wherein the first structured metal layer, the second structured metal layer, and the plurality of vias are designed such that a gate-source current path between the power transistor chip and the source sense package terminal pad is provided only on one of the first and second structured metal layers while a drain-source current path between the source electrode metallization of the power transistor chip and the source package terminal pad is at least on the other structured metal layer of the multi-layer laminate substrate.

2. The transistor package of claim 1, wherein the source sense package terminal pad and the source package terminal pad are formed by a continuous metal segment of the second structured metal layer.

3. The transistor package of claim 1, wherein the drain-source current path is on the first and second structured metal layers, and wherein the gate-source current path is only on the second structured metal layer.

4. The transistor package of claim 3, wherein the drain-source current path on the first and second structured metal layers is in a lateral direction Y and the gate-source current path on the second structured metal layer is in a lateral direction X, and wherein the lateral direction Y and the lateral direction X are different from each other.

5. The transistor package of claim 1, wherein the source sense package terminal pad and the source package terminal pad are formed by separate metal segments of the second structured metal layer.

6. The transistor package of claim 5, wherein the drain-source current path is on the first and second structured metal layers, and wherein the gate-source current path is only on the first structured metal layer.

7. The transistor package of claim 6, wherein the drain-source current path on the first and second structured metal layers is in a lateral direction Y and the gate-source current path on the first structured metal layer is also at least partially in the lateral direction Y.

8. The transistor package of claim 5, wherein the drain-source current path is only on the second structured metal layer, and wherein the gate-source current path is only on the first structured metal layer.

9. The transistor package of claim 8, wherein the drain-source current path on the second structured metal layer is in a lateral direction Y and the gate-source current path on the first structured metal layer is also at least partially in the lateral direction Y.

10. The transistor package of claim 5, wherein the separate source sense package terminal pad is connected to the first metal layer by a dedicated via through which no drain-source current is flowing.

11. The transistor package of claim 1, wherein the first structured metal layer comprises a multi-finger drain segment connected to the drain electrode metallization and a multi-finger source segment connected to the source electrode metallization, and wherein the multi-finger drain segment and the multi-finger source segment are interdigitated.

12. The transistor package of claim 1, wherein the source package terminal pad is arranged along a first side of the transistor package, the drain package terminal pad is arranged along a second side opposite the first side of the transistor package, and the gate package terminal pad is arranged at a corner of the first side of the transistor package.

13. The transistor package of claim 1, wherein the source package terminal pad is arranged along a first side of the transistor package, the drain package terminal pad is arranged along a second side opposite the first side of the transistor package, and the gate package terminal pad is arranged at a third side of the transistor package in a region spaced apart from a corner of the first or second side of the transistor package.

14. The transistor package of claim 1, further comprising:
a mold compound embedding the power transistor chip and covering the multi-layer laminate substrate outside the area where the power transistor chip is placed.

15. The transistor package of claim 1, wherein the power transistor chip is a HEMT transistor chip and/or a GaN transistor chip.

16. The transistor package of claim 1, wherein the power transistor chip is configured to switch drain-source voltages equal to or greater than 50 V.
